(19) United States
(12) Patent Application Publication
(10) Pub. No.: US 2026/0196449 A1
(43) Pub. Date: Jul. 9, 2026

(54) PLASMA PROCESSING METHOD

(71) Applicant: Hitachi High-Tech Corporation, Minato-ku, Tokyo (JP)

(72) Inventor: Kiyohiko SATOH, Tokyo (JP)

(21) Appl. No.: 18/839,964

(22) PCT Filed: Jul. 25, 2023
(86) PCT No.: PCT/JP2023/027232

§ 371 Date: Aug. 20, 2024

(51) Int. Cl. H01J 37/32; H10P 14/60; H10P 50/28

(52) U.S. Cl. CPC H01J 37/32678; H01J 37/32082; H10P 14/6304; H10P 14/6316; H10P 50/283; H01J 2237/332; H01J 2237/334; H01J 2237/3387

(57) ABSTRACT

A plasma processing method for plasma-etching a target etch layer of a substrate to be processed 301 including a target etch layer 201 and a sacrificial layer 200 patterned above the target etch layer includes: a first step of depositing a silicon element containing film 204 on the sacrificial layer; a second step of nitriding the silicon element containing film deposited on the sacrificial layer and the silicon element containing film deposited on the target etch layer using plasma generated by a nitrogen element containing gas after the first step; and a third step of oxidizing the silicon element containing film using plasma generated by an oxygen element containing gas after the second step.

### TECHNICAL FIELD

The present invention relates to a plasma processing method for a semiconductor substrate.

### BACKGROUND ART

At present, due to a difficulty of direct resolution by exposure, pattern reduction methods with a double pitch and a quadruple pitch are widely used. These methods are referred to as self-aligned double patterning (SADP) or self-aligned quadruple patterning (SAQP), and are essential techniques in a semiconductor manufacturing process for forming a fine pattern.

For example, PTL 1 or NPL 1 discloses a SADP process flow. First, a target etch layer, a sacrificial layer, and a resist are formed and coated in this order, and the resist is developed and subjected to patterning. Next, sacrificial layer is etched using the resist as a mask. After the resist is removed, an oxide film or the like is formed on a sacrificial layer pattern using atomic layer deposition (ALD) or the like. The formed oxide film or the like is referred to as a spacer. Subsequently, a portion deposited on an upper portion of the sacrificial layer pattern and a bottom portion between the sacrificial layer patterns (that is, on the target etch layer) is selectively removed by etching from the spacer. Further, by removing the sacrificial layer, a structure is formed in which only the spacer formed on a side wall of the sacrificial layer pattern remains on the target etch layer. Thereafter, the target etch layer is processed using the remaining spacer as the mask. By using such a method, a pattern having a dimension of ½ of an original pitch (double pitch) can be formed.

### CITATION LIST

### Patent Literature

PTL 1: JP2010-114424A

### Non Patent Literature

NPL 1: T. Shibata et al., “ALD-SiO2 deposition and CD slimming techniques for double patterning and a heater-less batch tool”, 2010 International Symposium on Semiconductor Manufacturing (ISSM)

### SUMMARY OF INVENTION

### Technical Problem

In an embodiment of SADP disclosed in the related art, a silicon oxide film or the like serving as the mask is formed around the sacrificial layer using a technique such as the ALD. Since the formation of the silicon oxide film using the ALD and the etching after the formation are performed by different apparatuses, a formation apparatus and an etching apparatus are repeatedly reciprocated. Accordingly, an area (footprint) occupied by the apparatus is increased, and it takes time to convey between the apparatuses.

### Solution to Problem

A plasma processing method according to an embodiment of the invention is a plasma processing method for plasma-etching a target etch layer of a substrate to be processed including the target etch layer and a sacrificial layer patterned above the target etch layer, and the plasma processing method includes: a first step of depositing a silicon element containing film on the sacrificial layer using plasma generated by a silicon element containing gas; a second step of nitriding the silicon element containing film deposited on the sacrificial layer and the silicon element containing film deposited on the target etch layer using plasma generated by a nitrogen element containing gas after the first step; a third step of oxidizing the silicon element containing film using plasma generated by an oxygen element containing gas after the second step; a fourth step of removing a silicon nitride film on the target etch layer or on the sacrificial layer after the third step; a fifth step of removing the sacrificial layer after the fourth step; and a sixth step of plasma-etching the target etch layer using a silicon oxide film formed on the target etch layer as a mask after the fifth step.

### Advantageous Effects of Invention

A plasma processing method capable of executing a SADP process can be performed in a consistent vacuum. Other problems and novel features will become apparent from description of the present specification and the accompanying drawings.

### BRIEF DESCRIPTION OF DRAWINGS

FIG. 1 is a process flow according to the present embodiment.

FIG. 2A is a diagram schematically showing a processing process by taking an SADP process as an example.

FIG. 2B is a diagram schematically showing the processing process by taking the SADP process as the example.

FIG. 2C is a diagram schematically showing the processing process by taking the SADP process as the example.

FIG. 2D is a diagram schematically showing the processing process by taking the SADP process as the example.

FIG. 2E is a diagram schematically showing the processing process by taking the SADP process as the example.

FIG. 2F is a diagram schematically showing the processing process by taking the SADP process as the example.

FIG. 2G is a diagram schematically showing the processing process by taking the SADP process as the example.

FIG. 2H is a diagram schematically showing the processing process by taking the SADP process as the example.

FIG. 3 is a schematic configuration diagram of a plasma processing apparatus.

FIG. 4 is a diagram schematically showing a mask (silicon oxide film) shape according to a comparative example.

### DESCRIPTION OF EMBODIMENTS

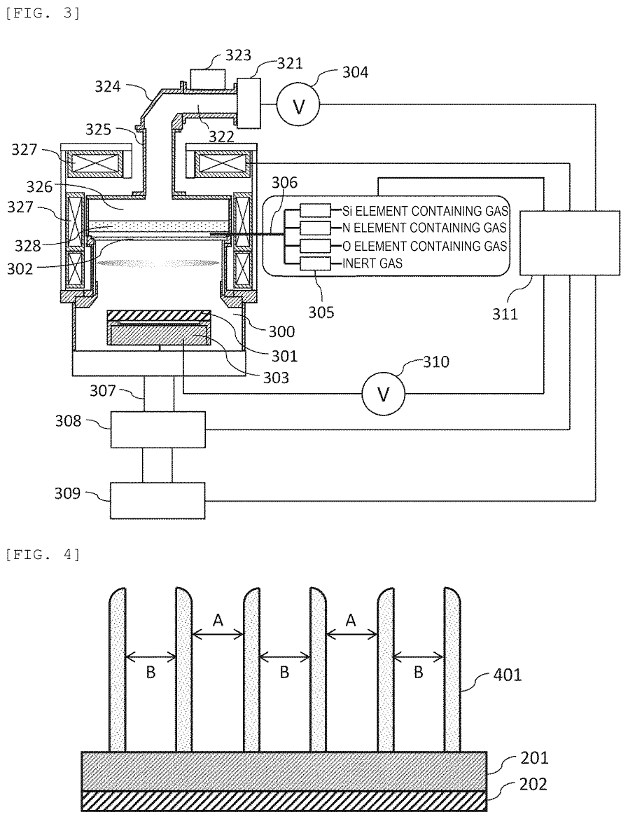

FIG. 3 shows an example of a plasma processing apparatus that performs a plasma process according to the present embodiment. Here, an example of a plasma processing apparatus that generates electron cyclotron resonance (ECR) excitation plasma will be described as the example of the plasma processing apparatus. In the ECR excitation plasma processing apparatus, plasma is generated by applying an external magnetic field using microwaves as an excitation source.

The plasma processing apparatus includes a sample stage 303 on which a substrate to be processed (wafer) 301 is placed in a vacuum chamber 300, and performs the plasma process on the substrate to be processed 301 by the plasma generated in the vacuum chamber 300. A substrate-biasing radio frequency power supply 310 is connected to the sample stage 303. By controlling an applied substrate bias (radio frequency power), it is possible to control directionality and energy of ions incident on the substrate to be processed 301. An exhaust pipe 307 is connected to the vacuum chamber 300, and a pressure control valve 308 that adjusts an internal pressure of the vacuum chamber 300 and a pump 309 are connected to the exhaust pipe 307. The pump 309 evacuates an inside of the vacuum chamber 300 via the exhaust pipe 307 and the pressure control valve 308, and maintains the vacuum chamber 300 in a low pressure state during the plasma process.

A microwave generation oscillator 321 generates microwaves by receiving power from a microwave power generator (plasma generation power supply) 304. Microwave generated by the microwave generation oscillator 321 is adjusted by a microwave matching unit 323 and propagated from a rectangular waveguide 322 to a circular waveguide 325 and a cavity chamber 326 via a converter 324, and the cavity chamber 326 resonates the propagated microwave.

The cavity chamber 326 and the vacuum chamber 300 are partitioned by a partition plate 328. The partition plate 328 is formed of a dielectric through which the microwave transmits and which maintains a vacuum state inside the vacuum chamber 300. Outside the vacuum chamber 300 and the cavity chamber 326, an electromagnetic coil 327 for forming a magnetic field inside the cavity chamber 326 and the vacuum chamber 300 and generating the electron cyclotron resonance is provided.

A shower plate 302 having a large number of holes for supplying a gas into the vacuum chamber 300 is provided, and a gas line 306 for supplying the gas is provided between the partition plate 328 and the shower plate 302. A flow rate of the gas is adjusted by a mass flow controller (MFC) 305, and the gas is supplied into the vacuum chamber 300 through the gas line 306. In order to obtain desired film quality of a film, the MFC 305 is preferably mounted in each gas system. Gases to be supplied by respective gas systems are, for example, a silicon element (Si) containing gas, a nitrogen element (N) containing gas, an oxygen element (O) containing gas, and an inert gas. The inert gas can be used for switching the gases or improving uniformity, and argon can be used as an example.

A control unit 311 controls the microwave power generator 304, the electromagnetic coil 327, the MFC 305, the pressure control valve 308, the pump 309, and the substrate-biasing radio frequency power supply 310 to execute the plasma process on the substrate to be processed 301.

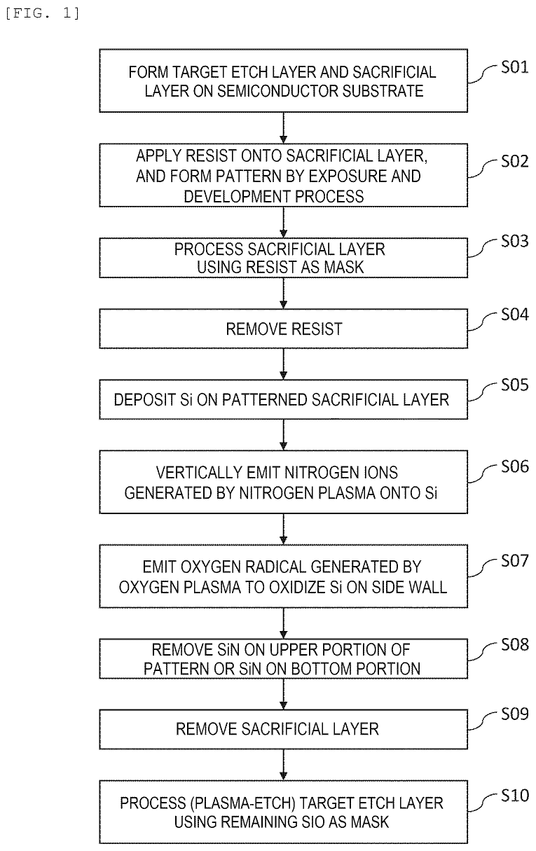

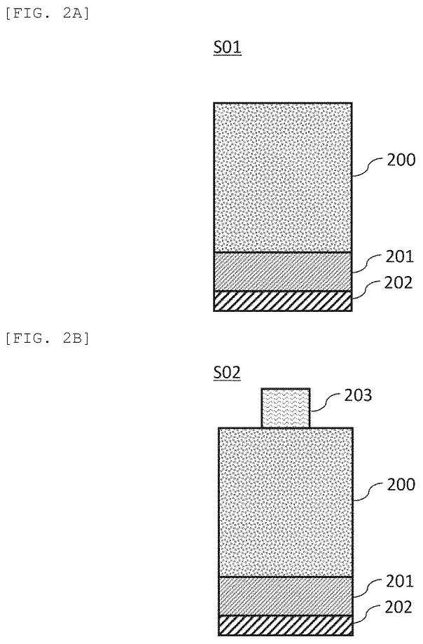

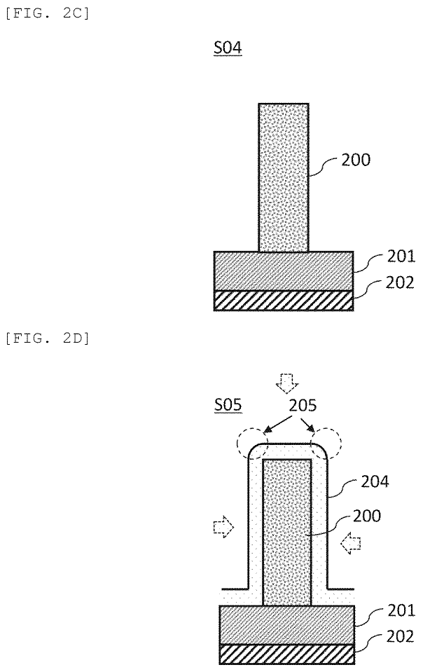

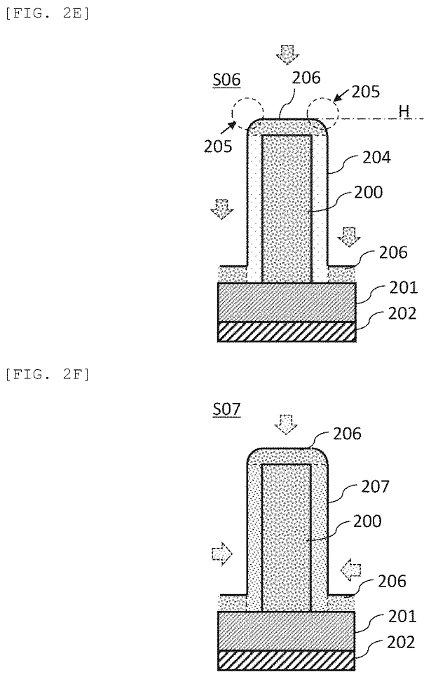

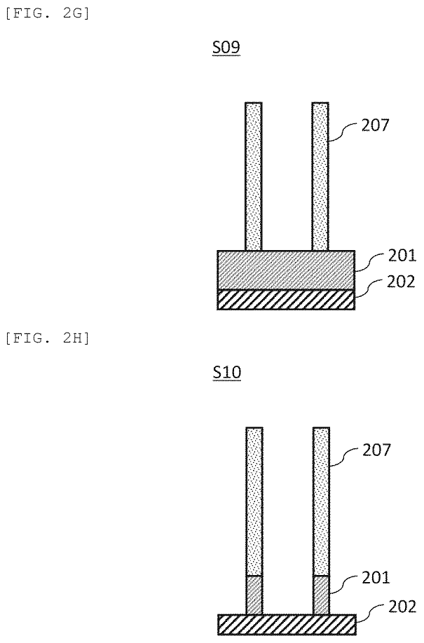

A process flow according to the present embodiment will be described with reference to FIGS. 1 and 2A to 2H. FIGS. 2A to 2H show a SADP process as an example. First, a target etch layer 201 and a sacrificial layer 200 are formed in this order on a semiconductor substrate 202 (S01). FIG. 2A shows a state in which step S01 is completed. The sacrificial layer is preferably a silicon nitride (SiN) film or a polysilicon (Poly-Si) film. In addition, the semiconductor substrate 202 may be a bare wafer, and may be in a state in which some base films are formed on the bare wafer. Next, a resist 203 is applied onto the sacrificial layer 200, and a pattern is formed by an exposure and development process (S02). FIG. 2B shows a state in which step S02 is completed. The substrate to be processed 301 on which the processes up to step S02 are completed is introduced into the plasma processing apparatus as shown in FIG. 3, and the following processes are performed.

First, the sacrificial layer 200 is processed (anisotropically etched) using the resist 203 as a mask (S03), and then the resist 203 is removed (S04). FIG. 2C shows a state in which step S04 is completed. Next, silicon is deposited on the sacrificial layer 200 on which the pattern is formed. By supplying the Si element containing gas from the gas line 306 and depositing a Si element containing film, a structure shown in FIG. 2D can be obtained. A silicon film 204 has an amorphous structure and is isotropically formed. However, shoulder loss 205 are formed at portions formed at corner portions of the sacrificial layer 200. As the silicon element containing gas, gas species such as tetrachlorosilane, dichlorosilane, trichlorosilane, dimethyldichlorosilane, trimethylchlorosilane, methyltrichlorosilane, monosilane, disilane, and trisilane can be used.

Next, the nitrogen element containing gas is supplied from the gas line 306, and nitrogen ions generated by nitrogen plasma are vertically emitted to the silicon film 204 (S06). As the nitrogen element containing gas, a gas such as nitrogen or ammonia can be used. The substrate bias is applied from the substrate-biasing radio frequency power supply 310 and the nitrogen ions are emitted from a direction perpendicular to a sample placement surface of the sample stage 303, so that a reaction between silicon and nitrogen ions proceeds from an upper surface of the silicon film 204. As a result, the silicon film 204 on a sacrificial layer pattern and the silicon film 204 on bottom portions (that is, on the target etch layer 201) are selectively nitrided to become a silicon nitride film 206, while the silicon film 204 deposited on side surfaces of the sacrificial layer pattern is maintained as it is. Accordingly, a structure shown in FIG. 2E is obtained. In FIG. 2E, a plane parallel to the sample placement surface of the sample stage 303 is shown as a horizontal plane H.

In the structure shown in FIG. 2E, the shoulder losses 205 also become the silicon nitride film 206. Since an upper surface of the shoulder loss 205 has an angle with respect to the horizontal plane H, a ratio of the nitrogen ions incident on the silicon film 204 decreases, so that a boundary between the silicon nitride film 206 on an upper surface of the sacrificial layer pattern and the silicon film 204 on the side surface of the sacrificial layer pattern is at least gentler than the upper surface of the shoulder loss 205 (in FIG. 2E, the boundary is drawn to be parallel to the horizontal plane H, but the boundary is not limited to being horizontal).

Next, the oxygen element containing gas is supplied from the gas line 306, and oxygen radicals generated by oxygen plasma are emitted to oxidize silicon on sidewalls of the sacrificial layer pattern (S07). As the oxygen element containing gas, a gas containing oxygen elements such as oxygen, carbon monoxide, carbon dioxide, or nitride oxygen (NO₂) may be used. FIG. 2F shows a state in which step S07 is completed, and the silicon film 204 remaining at a stage in which step S06 is completed is oxidized to become a silicon oxide film 207.

As described above, a temperature is about 100° C. or less at which an ion impact by the plasma obtained by the nitrogen element containing gas in step S06 and sidewall oxidation by the plasma obtained by the oxygen element containing gas in step S07 can be effectively performed. From this point of view, the process flow according to the present embodiment is preferably performed by the ECR excitation plasma processing apparatus as shown in FIG. 3.

Thereafter, the silicon nitride film 206 on the sacrificial layer pattern and the silicon nitride film 206 on the bottom portions are removed (S08), and the sacrificial layer is further removed (S09). FIG. 2G shows a state in which step S09 is completed. Thereafter, the target etch layer 201 is processed (anisotropically etched) using the remaining silicon oxide film 207 as the mask (S10). FIG. 2H shows a state in which step S10 is completed.

Steps S05 to S07 in the process flow may be repeatedly performed in a plurality of cycles by setting steps S05 to S07 as one cycle instead of a single process to obtain the structure shown in FIG. 2F. Accordingly, the silicon oxide film 207 having a high density can be obtained, and etching resistance as the mask can be improved.

Hereinafter, effects of the plasma process according to the present embodiment will be described. In a SADP process in the related art, a shoulder loss is generated when the silicon oxide film is formed as the mask. This state is shown in FIG. 4 as a comparative example. FIG. 4 shows an example of a case in which a silicon oxide film 401 as the mask is formed on the target etch layer 201 by ALD. In this case, a gap A where the shoulder losses of the mask face each other and a gap B where non-shoulder losses of the mask face each other are generated, and an amount of ions incident on the gap A becomes larger than an amount of ions incident on the gap B when the target etch layer 201 is etched. Therefore, a variation in a processing width of the target etch layer 201 occurs between the gap A and the gap B. In a fine pattern, such a variation in the processing width cannot be ignored.

In contrast, in the process flow according to the present embodiment, as shown in FIG. 2G, the silicon oxide film 207 as the mask is formed after the shoulder losses formed at the time of depositing the silicon film are removed. Accordingly, at least inclination of a top surface of the silicon oxide film 207 with respect to the horizontal plane becomes gentler than the shoulder losses at the time of depositing the silicon film, and a dimensional variation of the pattern of the target etch layer 201 that is finally obtained can be reduced.

Further, by forming the silicon oxide film as the mask by the oxidation with oxygen radicals, film quality can be improved, and an oxide film mask having high resistance can be formed.

The invention is not limited to the above-described embodiment, and includes various modifications. For example, the embodiment and the modification described above have been described in detail to facilitate understanding of the invention, and the invention is not necessarily limited to those including all the configurations described above. A part of the configuration of one embodiment and modification can be replaced with the configuration of another embodiment and modification, and the configuration of one embodiment and modification can be added to the configuration of another embodiment and modification. A part of configuration in each of the embodiment and the modification may be added to, deleted from, or replaced with another configuration.

### REFERENCE SIGNS LIST

200: sacrificial layer
201: target etch layer
202: semiconductor substrate
203: resist
204: silicon film
205: shoulder loss
206: silicon nitride film
207: silicon oxide film
300: vacuum chamber
301: substrate to be processed
302: shower plate
303: sample stage
304: microwave power generator
305: mass flow controller
306: gas line
307: exhaust pipe
308: pressure control valve
309: pump
310: substrate-biasing radio frequency power supply
311: control unit
321: microwave generation oscillator
322: rectangular waveguide
323: microwave matching unit
324: converter
325: circular waveguide
326: cavity chamber
327: electromagnetic coil
328: partition plate

1. A plasma processing method for plasma-etching a target etch layer of a substrate to be processed including the target etch layer and a sacrificial layer patterned above the target etch the plasma processing method comprising:
a first step of depositing a silicon element containing film on, the sacrificial layer using plasma generated by a silicon element containing gas;
a second step of nitriding the silicon element containing film deposited on the sacrificial layer and the silicon element containing film deposited on the target etch layer using plasma generated by a nitrogen element containing gas after the first step;
a third step of oxidizing the silicon element containing film using plasma generated by an oxygen element containing gas after the second step;
a fourth step of removing a silicon nitride film on the target etch layer or on the sacrificial layer after the third step;
a fifth step of removing the sacrificial layer after the fourth step; and
a sixth step of plasma-etching the target etch layer using a silicon oxide film formed on the target etch layer as a mask after the fifth step.

2. The plasma processing method according to claim 1, wherein
the sacrificial layer is the silicon nitride film or a polysilicon film.

3. The plasma processing method according to claim 1, wherein
the first step to the third step are repeated a predetermined number of times.

4. The plasma processing method according to claim 2, wherein
the first step to the third step are repeated a predetermined number of times.

5. The plasma processing method according to claim 1, wherein
the second step is performed while radio frequency power is supplied to a sample stage on which the substrate to be processed is placed.

6. The plasma processing method according to claim 2, wherein
the second step is performed while radio frequency power is supplied to a sample stage on which the substrate to be processed is placed.

7. The plasma processing method according to claim 1, wherein
the silicon oxide film is a film obtained by oxidizing the silicon element containing film deposited on a side surface of the sacrificial layer in the third step.

8. The plasma processing method according to claim 2, wherein
the silicon oxide film is a film obtained by oxidizing the silicon element containing film deposited on a side surface of the sacrificial layer in the third step.

9. The plasma processing method according to claim 1, wherein
the plasma in the first step to the third step is plasma generated by electron cyclotron resonance.

10. The plasma processing method according to claim 2, wherein
the plasma in the first step to the third step is plasma generated by electron cyclotron resonance.
